(19) United States
(12) Patent Application Publication
(10) Pub. No.: US 2025/0220807 A1
(43) Pub. Date: Jul. 3, 2025

(54) TEST PAD

(71) Applicant: CHIPBOND TECHNOLOGY CORPORATION, Hsinchu (TW)

(72) Inventors: Kung-Tzu Tu, Kaohsiung City (TW); Gwo-Shyan Sheu, Kaohsiung City (TW); Hsin-Hao Huang, Kaohsiung City (TW); Pei-Wen Wang, Taichung City (TW); Yu-Chen Ma, Kaohsiung City (TW)

(21) Appl. No.: 18/964,797

(22) Filed: Dec. 2, 2024

(30) Foreign Application Priority Data
Dec. 27, 2023 (TW) 112151132

(51) Int. Cl. H05K 1/02

(52) U.S. Cl. CPC H05K 1/0268; H05K 2201/09381

(57) ABSTRACT

A test pad and at least one circuit line are arranged on a substrate, and the test pad is provided for contacting of a contact portion of a probe. A groove on the test pad is provided to restrict the contact portion to prevent the contact portion from sliding out the test pad.

### CROSS-REFERENCE TO RELATED APPLICATIONS

This application claims priority to R.O.C patent application No. 112151132 filed Dec. 27, 2023, the disclosure of which is hereby incorporated by reference in its entirety.

### FIELD OF THE INVENTION

This invention relates to a test pad, and more particularly to a test pad able to avoid probe slipping.

### BACKGROUND OF THE INVENTION

With reference to FIGS. 1 to 3, a conventional circuit board 10 includes a substrate 11 and a circuit layer 12. The circuit layer 12 has at least one circuit line 12a and at least one test pad 12b, and the circuit layer 12 is partially covered by a solder resist layer 13. While warpage of the substrate 11 is found, the test pad 12b is bent or tilted with the substrate 11.

With reference to FIGS. 2 and 3, a probe 20 of a testing device (e.g. probe card) is moved to contact the test pad 12b for testing, and if the substrate 11 is warped, a contact portion 21 of the probe 20 may slide out of the test pad 12b to cause false testing result. In order to prevent the contact portion 21 from sliding out the test pad 12b, it is required to apply more downforce on the probe 20 to contact the test pad 12b, but friction between the contact portion 21 and the test pad 12b is also increased to generate abrasion on the contact portion 21 and the test pad 12b. As a result, service life of the probe 20 and the circuit board 10 may be shortened.

Furthermore, abrasion particles may be observed on the contact portion 21 and/or the test pad 12b due to the increased friction between the contact portion 21 and the test pad 12b. The abrasion particles on the contact portion 21 or the test pad 12b may cause short circuit of the testing device or the circuit board 10 to lower product yield and testing performance. In order to avoid short circuit, cleaning frequency of the probe 20 needs to be increased, but it may reduce testing efficiency.

### SUMMARY OF THE INVENTION

One object of the present invention is to provide a test pad which is arranged on a substrate, a groove on the test pad can prevent a contact portion of a probe from sliding out the test pad.

A test pad of the present invention is arranged on a substrate with at least one circuit line, and it is provided for contacting of a contact portion of a probe during testing. The test pad includes at least one groove which is provided to prevent the contact portion from sliding out the test pad, and an edge of the groove is provided for contacting of the contact portion.

As the contact portion of the probe contacts the test pad, the groove can restrict the contact portion to prevent the contact portion from sliding out the test pad.

### BRIEF DESCRIPTION OF DRAWINGS

FIG. 1 is a top view diagram illustrating a conventional circuit board with test pads.

FIG. 2 is a cross-section view diagram illustrating a conventional test pad.

FIG. 3 is a cross-section view diagram illustrating a conventional test pad.

FIG. 4 is a top view diagram illustrating a circuit board with test pads in accordance with one embodiment of the present invention.

FIG. 5 is a top view diagram illustrating a test pad in accordance with one embodiment of the present invention.

FIG. 6 is a cross-section view diagram illustrating a test pad in accordance with one embodiment of the present invention.

FIGS. 7 to 11 are top view diagrams illustrating test pads in accordance with other embodiments of the present invention.

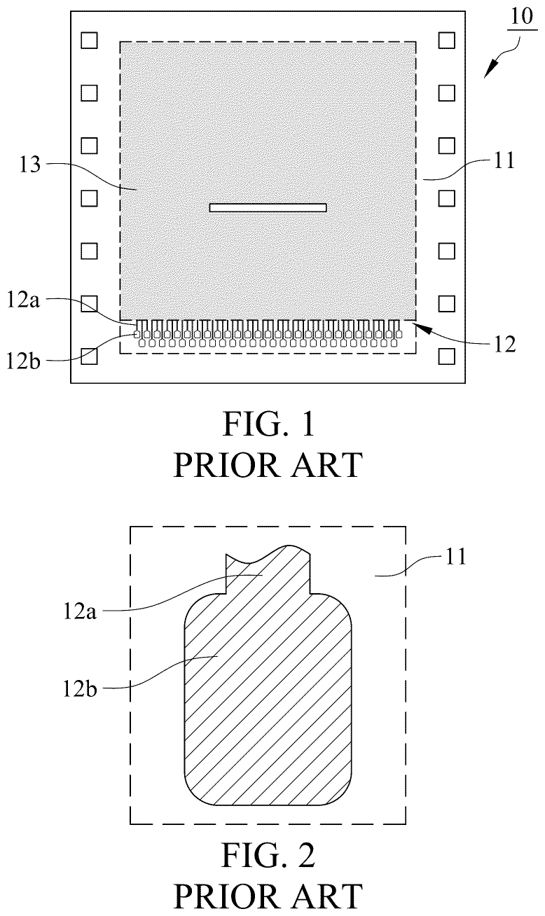

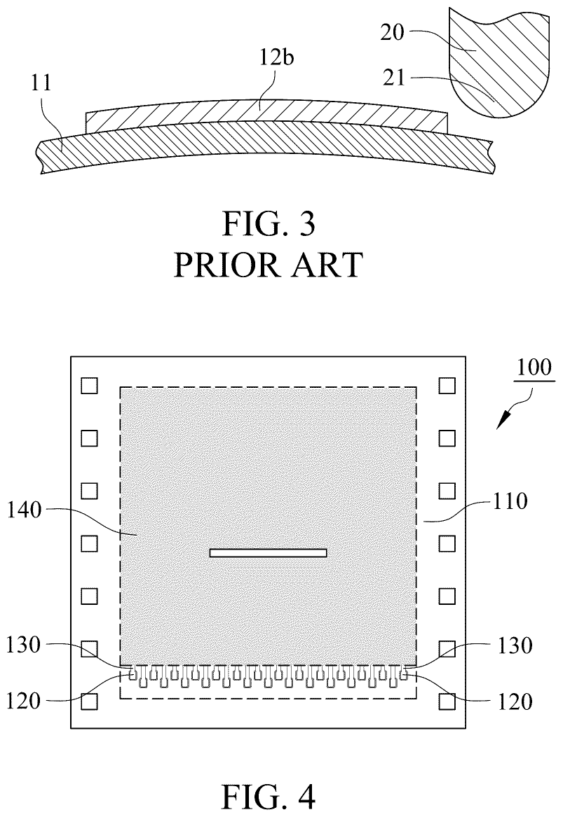

### DETAILED DESCRIPTION OF THE INVENTION

With reference to FIGS. 4 to 6, a test pad 120 and at least one circuit line 130 are provided on a substrate 110 to become a circuit board 100, the circuit line 130 is partially covered by a solder resist layer 140. The test pad 120 and the circuit line 130 are connected with each other and their formation method is not limited in the present invention. Preferably, the test pad 120 and the circuit line 130 are formed on the substrate 110 after etching a metal layer (not shown) provided on the substrate 110 which can be made of glass, silicon or flexible material, such as polyimide (PI) and polyethylene terephthalate (PET).

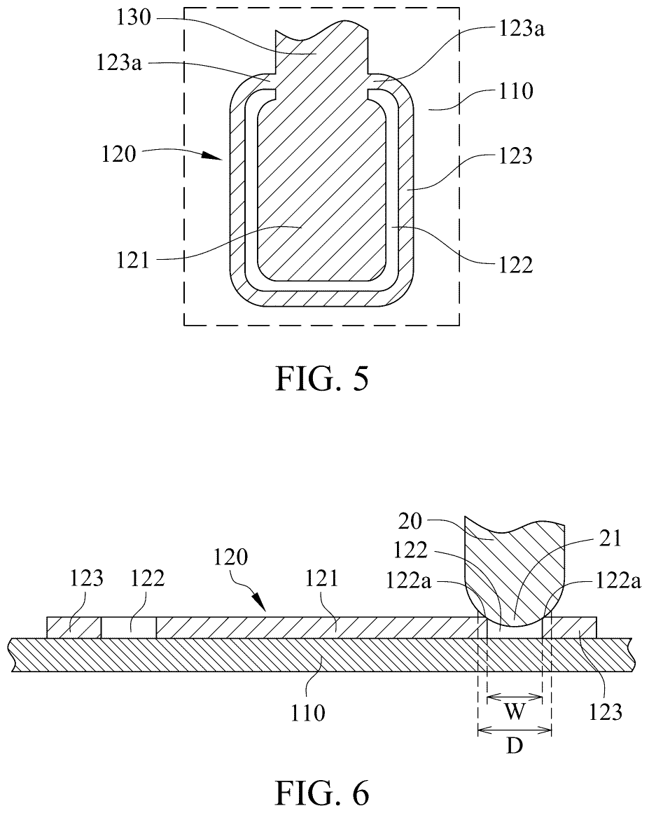

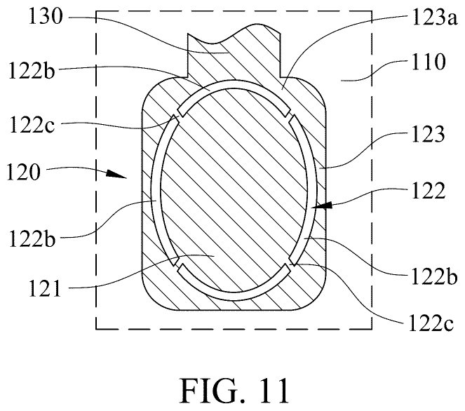

With reference to FIGS. 4 to 6, the test pad 120 is provided to be contacted by a contact portion 21 of a probe 20 of a testing device (e.g. probe card) during testing. There is at least one groove 122 on the test pad 120, the groove 122 is used to restrict the contact portion 21 of the probe 20 to prevent the contact portion 21 from sliding out the test pad 120 during testing. Shape and size of the groove 122 are not limited in the present invention, the groove 122 can be any shape or size as shown in FIGS. 5 and 7 to 11. Preferably, the groove 122 is a closed groove but not a circular groove. With reference to FIG. 6, a width W of the groove 122 is less than or equal to an outer diameter D of the contact portion 21 of the probe 20.

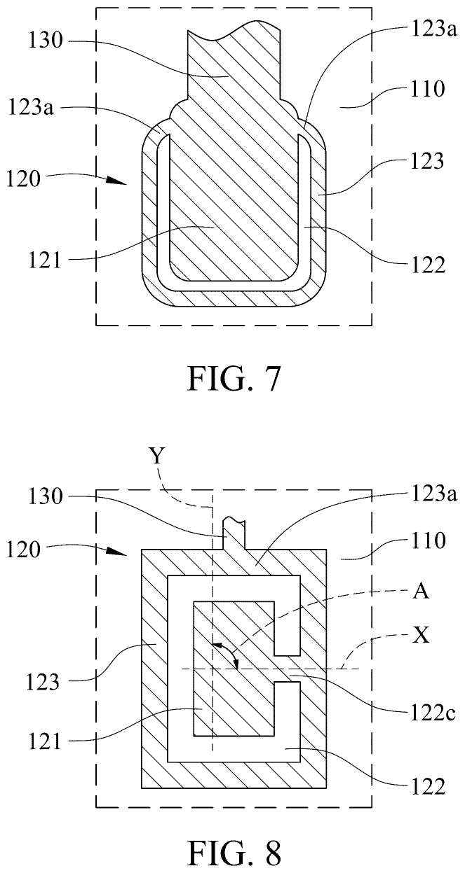

With reference to FIGS. 5 and 6, the test pad 120 preferably further includes a body 121 and a restriction portion 123. The groove 122 is located between the body 121 and the restriction portion 123, the body 121 is connected to the circuit line 130 and surrounded by the groove 122, and the restriction portion 123 is electrically connected to the body 121 and surrounds the groove 122. In this embodiment, an end 123a of the restriction portion 123 is connected to the circuit line 130, and the area of the body 121 is larger than or equal to that of the groove 122. With reference to FIG. 7, the end 123a of the restriction portion 123 is connected to the body 121 in another embodiment.

With reference to FIGS. 5 and 6, the movement of the contact portion 21 is restricted by the groove 122 when the contact portion 21 of the probe 20 is contacting the test pad 120 during testing, and the contact portion 21 can contact an edge 122a of the groove 122 as the probe 20 is sliding to the groove 122 so the probe 20 still can test the test pad 120.

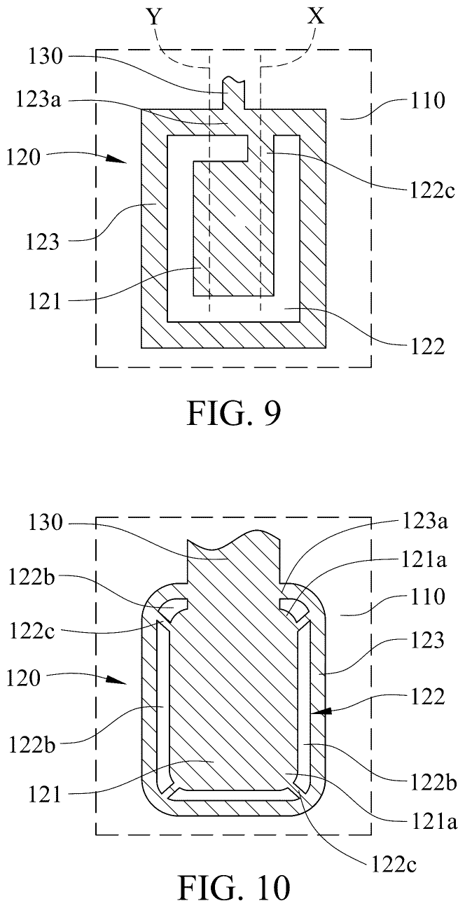

In another embodiment as shown in FIG. 8, the end 123a of the restriction portion 123 is connected to the circuit line 130 and the test pad 120 further includes a connection portion 122c. Both ends of the connection portion 122c are connected to the body 121 and the restriction portion 123, respectively. The restriction portion 123, the connection portion 122c and the body 121 are passed by a first imaginary line X, the restriction portion 123, the groove 122 and the body 121 are passed by a second imaginary line Y. In this embodiment as shown in FIG. 8, there is an included angle A between the first imaginary line X and the second imaginary line Y. Different to the embodiment as shown in FIG. 8, the first imaginary line X is parallel to the second imaginary line Y in another embodiment as shown in FIG. 9.

In other embodiments as shown in FIGS. 9 and 10, the test pad 120 includes multiple grooves 122b which are not connected to one another. At least one connection portion 122c is located between the adjacent grooves 122b, and both ends of the connection portion 122c are connected to the body 121 and the restriction portion 123, respectively. The connection portion 122c is preferably designed to be located on one corner 121a of the body 121 to improve the connection strength of the body 121 and the restriction portion 123.

While the contact portion 21 of the probe 20 is contacting the test pad 120, the groove 122 is provided to restrict the contact portion 21 to prevent the contact portion 21 from sliding out the test pad 120. Consequently, the present invention does not need to increase downforce of the probe 20 to avoid the probe 20 from slipping and can overcome the prior art issues of friction and short circuit between the contact portion and the test pad and increased cleaning frequency of the probe.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A test pad arranged on a substrate with at least one circuit line and configured for contacting of a contact portion of a probe, characterized in that the test pad comprises at least one groove, the at least one groove is configured to restrict the contact portion of the probe from sliding out the test pad, and an edge of the at least one groove is configured for contacting of the contact portion of the probe.

2. The test pad in accordance with claim 1, wherein a width of the at least one groove is less than or equal to an outer diameter of the contact portion of the probe.

3. The test pad in accordance with claim 1 further comprises a body and a restriction portion, wherein the at least one groove is located between the body and the restriction portion.

4. The test pad in accordance with claim 3, wherein the body is surrounded by the at least one groove.

5. The test pad in accordance with claim 4, wherein the at least one groove is surrounded by the restriction portion.

6. The test pad in accordance with claim 3, wherein an area of the body is greater than or equal to that of the at least one groove.

7. The test pad in accordance with claim 3, wherein the body is connected to the at least one circuit line, and an end of the restriction portion is connected to the at least one circuit line.

8. The test pad in accordance with claim 3, wherein the body is connected to the at least one circuit line, and an end of the restriction portion is connected to the body.

9. The test pad in accordance with claim 3 further comprises a connection portion, wherein both ends of the connection portion are connected to the body and the restriction portion, respectively, an end of the restriction portion is connected to the at least one circuit line, wherein the restriction portion, the connection portion and the body are passed by a first imaginary line, the restriction portion, the at least one groove and the body are passed by a second imaginary line, and there is an included angle between the first and second imaginary lines.

10. The test pad in accordance with claim 3 further comprises a connection portion, wherein both ends of the connection portion are connected to the body and the restriction portion, respectively, an end of the restriction portion is connected to the at least one circuit line, wherein the restriction portion, the connection portion and the body are passed by a first imaginary line, the restriction portion, the at least one groove and the body are passed by a second imaginary line, and the first imaginary line is parallel to the second imaginary line.

11. The test pad in accordance with claim 3 comprises a plurality of grooves, wherein the plurality of grooves are not connected to one another, there is at least one connection portion between the adjacent grooves, and both ends of the at least one connection portion are connected to the body and the restriction portion, respectively.

12. The test pad in accordance with claim 9, wherein the at least one connection portion is located at a corner of the body.

13. The test pad in accordance with claim 1 further comprises a body, wherein an area of the body is greater than or equal to that of the at least one groove.
